(19) United States
(12) Patent Application Publication
(10) Pub. No.: US 2025/0392103 A1
(43) Pub. Date: Dec. 25, 2025

(54) VERTICAL CAVITY LIGHT-EMITTING ELEMENT

(71) Applicant: STANLEY ELECTRIC CO., LTD., Meguro-ku, Tokyo (JP)

(72) Inventor: Masaru KURAMOTO, Tokyo (JP)

(73) Assignee: STANLEY ELECTRIC CO., LTD., Meguro-ku, Tokyo (JP)

(21) Appl. No.: 18/842,138

(22) PCT Filed: Feb. 22, 2023
(86) PCT No.: PCT/JP2023/006504

§ 371 Date: Apr. 10, 2025

(30) Foreign Application Priority Data
Mar. 1, 2022 (JP) 2022-030773

(51) Int. Cl. H01S 5/183; H01S 5/02; H01S 5/042

(52) U.S. Cl. CPC H01S 5/18369; H01S 5/0207; H01S 5/04253; H01S 5/04254; H01S 5/18333; H01S 5/18386

(57) ABSTRACT

A vertical cavity light-emitting element includes a first multilayer reflector, a semiconductor structure layer, a second multilayer reflector, and a current confinement structure. The current confinement structure concentrates a current in one region of an active layer of the semiconductor structure layer. The vertical cavity light-emitting element has a concave reflective structure disposed on a lower surface of a gallium-nitride-based semiconductor substrate or in a region below the lower surface. The concave reflective structure has a concave reflecting surface that extends to an outside of the one region in a top view viewed in a direction perpendicular to an upper surface of the gallium-nitride-based semiconductor substrate and is opposed to the first multilayer reflector.

### TECHNICAL FIELD

The present invention relates to a vertical cavity light-emitting element, such as a vertical cavity surface emitting laser (VCSEL).

### BACKGROUND ART

Conventionally, as one of the semiconductor lasers, there has been known a vertical cavity-type semiconductor surface emitting laser (hereinafter also simply referred to as a surface emitting laser) including a semiconductor layer that emits light by application of voltage and multilayer reflectors opposed to one another with the semiconductor layer interposed therebetween. For example, Patent Document 1 discloses a vertical cavity-type semiconductor laser having an n-electrode and a p-electrode connected to an n-type semiconductor layer and a p-type semiconductor layer, respectively.
Patent Document 1: JP-A-2017-98328

### DISCLOSURE OF THE INVENTION

### Problems to be Solved by the Invention

For example, in a vertical cavity light-emitting element, such as a surface emitting laser, an optical resonator is formed by opposing reflectors. For example, in the surface emitting laser, when a voltage is applied to a semiconductor layer through an electrode, light emitted from the semiconductor layer resonates in the optical resonator, generating laser light.

However, for example, a vertical cavity-type semiconductor laser element is low in luminous efficiency compared with a horizontal cavity-type semiconductor laser having a resonator in an in-plane direction of a semiconductor layer including an active layer, which is an example of a problem.

In light emitted from the vertical cavity-type semiconductor laser element, a transverse mode tends to be multimode rather than single-mode. Therefore, it has been difficult to obtain a transverse mode light in a stable single mode.

The present invention has been made in consideration of the above-described points and it is an object to provide a vertical cavity light-emitting element that has high luminous efficiency and output and allows stably emitting a single-mode light.

### Solutions to the Problems

A vertical cavity light-emitting element according to the present invention includes a gallium-nitride-based semiconductor substrate, a first multilayer reflector, a semiconductor structure layer, a second multilayer reflector, and a current confinement structure. The first multilayer reflector is made of a nitride semiconductor formed on the substrate. The semiconductor structure layer includes a first semiconductor layer, an active layer, and a second semiconductor layer. The first semiconductor layer is made of a nitride semiconductor having a first conductivity type formed on the first multilayer reflector. The active layer is made of a nitride semiconductor formed on the first semiconductor layer. The second semiconductor layer is formed on the active layer and made of a nitride semiconductor having a second conductivity type opposite of the first conductivity type. The second multilayer reflector is formed on the semiconductor structure layer. The second multilayer reflector configures a resonator between the first multilayer reflector and the second multilayer reflector. The current confinement structure is formed between the first multilayer reflector and the second multilayer reflector to concentrate a current in one region of the active layer. The vertical cavity light-emitting element has a reflective structure disposed on a lower surface of the gallium-nitride-based semiconductor substrate or in a region below the lower surface. The reflective structure has a concave reflecting surface that extends to an outside of the one region in a top view viewed in a direction perpendicular to an upper surface of the gallium-nitride-based semiconductor substrate and is opposed to the first multilayer reflector.

### BRIEF DESCRIPTION OF THE DRAWINGS

FIG. 1 is a perspective view of a surface emitting laser of Embodiment 1.

FIG. 2 is a top view of the surface emitting laser of Embodiment 1.

FIG. 3 is a cross-sectional view of the surface emitting laser of Embodiment 1.

FIG. 4 a top view of a surface emitting laser of Modification 1.

FIG. 5 is a cross-sectional view of a surface emitting laser of Modification 2.

FIG. 6 is a cross-sectional view of a surface emitting laser of Modification 3.

FIG. 7 is a cross-sectional view of a surface emitting laser of another Modification.

FIG. 8 is a cross-sectional view of a surface emitting laser of Embodiment 2.

### DESCRIPTION OF PREFERRED EMBODIMENTS

The following describes embodiments of the present invention in detail. While in the following description, a description will be made using a semiconductor surface emitting laser element as an example, the present invention is applicable, not only to a surface emitting laser, but also to various kinds of vertical cavity light-emitting elements, such as a vertical cavity-type light-emitting diode.

### Embodiment 1

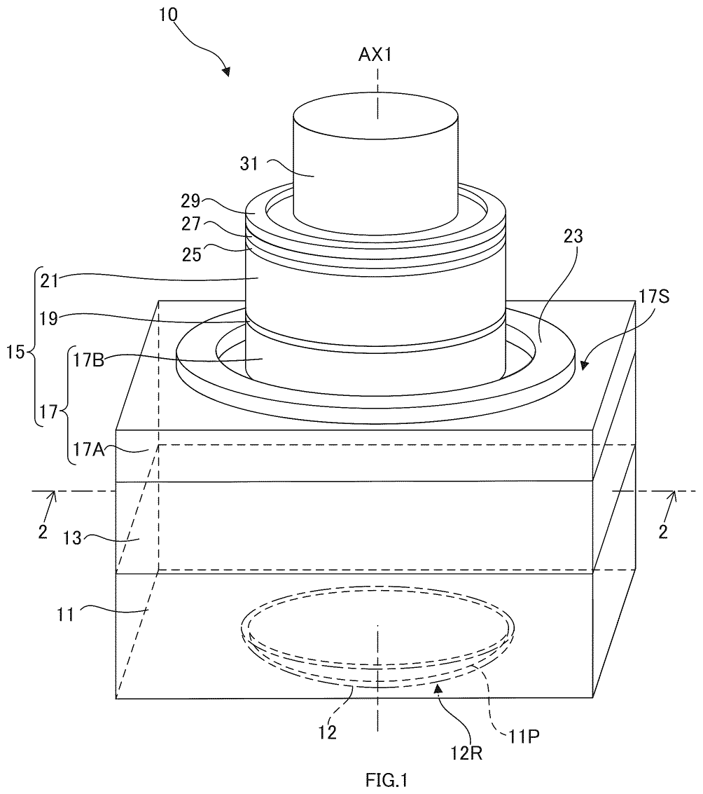

FIG. 1 is a perspective view of a vertical cavity surface emitting laser (VCSEL, hereinafter also simply referred to as a surface emitting laser) 10 according to Embodiment 1.

A substrate 11 is a gallium-nitride-based semiconductor substrate, for example, an undoped GaN substrate. The substrate 11 is, for example, a substrate with a rectangular upper surface shape. An upper surface of the substrate 11 is a surface offset by 0.5° in a direction from a C-plane to an M-plane. In addition, the upper surface of the substrate 11 is hardly offset in a direction from the C-plane to an A-plane, and an offset angle in the direction from the C-plane to the A-plane is 0±0.01°. In the following description, an axis passing through the center of the upper surface of the substrate 11 and perpendicular to the upper surface is described as a center axis AX1.

In the surface emitting laser 10, the substrate 11 preferably has high optical transparency since the substrate 11 is also disposed in the resonator. Therefore, the substrate 11 is preferably undoped.

A convex portion 11P is a convex portion made of a curved surface that is convex downward formed in a circular region around the center axis AX1 on the lower surface of the substrate 11. In this embodiment, the convex portion 11P has a plano-convex lens shape. In this embodiment, an optical axis of the lens shape formed by the convex portion 11P coincides with the center axis AX1.

A back surface multilayer reflector 12 (dash-dot-dot line in the drawing) is a dielectric multilayer reflector made of a dielectric film formed on a surface of the convex portion 11P. The back surface multilayer reflector 12 is a dielectric multilayer reflector in which a low refractive-index dielectric film made of SiO₂ and a high refractive-index dielectric film made of Nb₂O₅ and having a refractive index higher than that of the low refractive-index dielectric film are alternately laminated.

In other words, the back surface multilayer reflector 12 is a distributed Bragg reflector (DBR) made of a dielectric material. In this embodiment, the back surface multilayer reflector 12 is made of four pairs of Nb₂O₅/SiO₂ layers formed on the surface of the convex portion 11P. The back surface multilayer reflector 12 and the convex portion 11P form a concave reflective structure 12R having a concave reflecting surface 12RS that is concave upward. In other words, an upper surface of the back surface multilayer reflector 12 is the concave reflecting surface 12RS.

A first multilayer reflector 13 is a semiconductor multilayer reflector made of a semiconductor layer that has been grown on the substrate 11. The first multilayer reflector 13 is formed by alternately laminating a low refractive-index semiconductor film having a composition of AlInN and a high refractive-index semiconductor film having a GaN composition and having a refractive index higher than that of the low refractive-index semiconductor film. In other words, the first multilayer reflector 13 is a distributed Bragg reflector (DBR) made of a semiconductor material.

For example, the first multilayer reflector 13 is formed by disposing a buffer layer having a GaN composition on the upper surface of the substrate 11 and alternately depositing films of the high refractive-index semiconductor film and the low refractive-index semiconductor film described above on the buffer layer. In this embodiment, the first multilayer reflector 13 is made of 35 pairs of GaN/AlInN layers laminated on a 1 μm GaN base layer formed on the upper surface of the substrate 11. The first multilayer reflector 13 with such a configuration has a reflectivity of approximately 80% relative to emitted light from an active layer 19.

A semiconductor structure layer 15 is a laminated structure made of a plurality of semiconductor layers formed on the first multilayer reflector 13. The semiconductor structure layer 15 has an n-type semiconductor layer (a first semiconductor layer) 17 formed on the first multilayer reflector 13, a light-emitting layer (or an active layer) 19 formed on the n-type semiconductor layer 17, and a p-type semiconductor layer (a second semiconductor layer) 21 formed on the active layer 19.

The n-type semiconductor layer 17 as a first conductivity type semiconductor layer is a semiconductor layer formed on the first multilayer reflector 13. The n-type semiconductor layer 17 is a semiconductor layer that has a GaN composition and is doped with Si as n-type impurities. The n-type semiconductor layer 17 has a prismatic-shaped lower portion 17A and a column-shaped upper portion 17B disposed on the lower portion 17A. Specifically, for example, the n-type semiconductor layer 17 has the column-shaped upper portion 17B projecting from an upper surface 17S of the prismatic-shaped lower portion 17A. In other words, the n-type semiconductor layer 17 has a mesa-shaped structure including the upper portion 17B.

The active layer 19 is a layer that is formed on the upper portion 17B of the n-type semiconductor layer 17 and has a quantum well structure including a well layer having an InGaN composition and a barrier layer having a GaN composition. In the surface emitting laser 10, light is generated in the active layer 19. In this embodiment, the active layer 19 is formed such that a luminescence center of the active layer 19 is brought on the center axis AX1.

The p-type semiconductor layer 21 as a second conductivity type semiconductor layer is a semiconductor layer having a GaN composition formed on the active layer 19. The p-type semiconductor layer 21 is doped with Mg as p-type impurities.

An n-electrode 23 is a metal electrode disposed on the upper surface 17S of the lower portion 17A of the n-type semiconductor layer 17 and electrically connected to the n-type semiconductor layer 17. The n-electrode 23 is formed into a ring shape so as to surround the upper portion 17B of the n-type semiconductor layer 17. The n-electrode 23 is electrically in contact with the n-type semiconductor layer 17 and forms a first electrode layer that supplies a current from an outside to the semiconductor structure layer 15.

An insulating layer 25 is a layer made of an insulator formed on the p-type semiconductor layer 21. The insulating layer 25 is formed of a substance having a refractive index lower than that of a material forming the p-type semiconductor layer 21, such as SiO₂. The insulating layer 25 is formed into a ring shape on the p-type semiconductor layer 21 and is provided with an opening (not illustrated) that exposes the p-type semiconductor layer 21 at a central portion.

A transparent electrode 27 is a metal oxide film having translucency formed on an upper surface of the insulating layer 25. The transparent electrode 27 covers the entire upper surface of the insulating layer 25 and an entire upper surface of the p-type semiconductor layer 21 exposed from the opening formed in the central portion of the insulating layer 25. As the metal oxide film forming the transparent electrode 27, for example, ITO or IZO having translucency relative to emitted light from the active layer 19 can be used.

A p-electrode 29 is a metal electrode formed on the transparent electrode 27. The p-electrode 29 is electrically connected to the upper surface of the p-type semiconductor layer 21 exposed from the above-described opening of the insulating layer 25 via the transparent electrode 27. The transparent electrode 27 and the p-electrode 29 form a second electrode layer that is electrically in contact with the p-type semiconductor layer 21 and supplies a current from the outside to the semiconductor structure layer 15. In this embodiment, the p-electrode 29 is formed on an upper surface of the transparent electrode 27 in a ring shape along an outer edge of the upper surface.

A second multilayer reflector 31 is a column-shaped multilayer reflector formed in a region surrounded by the p-electrode 29 on the upper surface of the transparent electrode 27. The second multilayer reflector 31 is a dielectric multilayer reflector in which a low refractive-index dielectric film made of SiO₂ and a high refractive-index dielectric film made of Nb₂O₅ and having a refractive index higher than that of the low refractive-index dielectric film are alternately laminated. In other words, the second multilayer reflector 31 is a distributed Bragg reflector (DBR) made of a dielectric material.

In this embodiment, the second multilayer reflector 31 is made of a spacer layer of Nb₂O₅ formed on the upper surface of the transparent electrode 27 and 10.5 pairs of Nb₂O₅/SiO₂ layers formed on the spacer layer. The second multilayer reflector 31 with such a configuration has a reflectivity of 99% or more relative to the emitted light from the active layer 19. The reflectivity of the second multilayer reflector 31 is higher than the reflectivity of the first multilayer reflector 13.

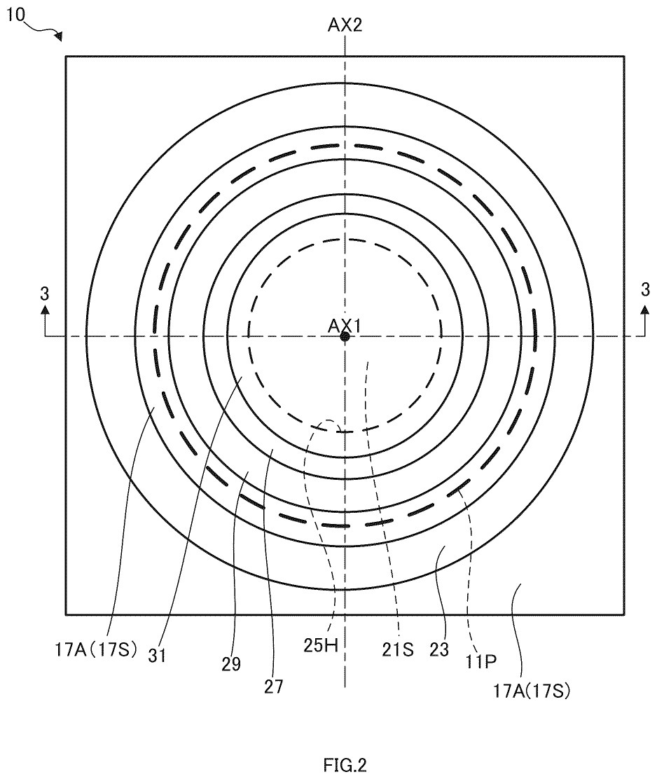

FIG. 2 is a top view of the surface emitting laser 10. In FIG. 2, an axis along an m-axis direction in the same plane as the upper surface of the substrate 11 is a lateral axis AX2. As described above, the surface emitting laser 10 has the semiconductor structure layer 15 that includes the n-type semiconductor layer 17 formed on the substrate 11 having a rectangular upper surface shape, the active layer 19 with a circular upper surface shape, and the p-type semiconductor layer 21 (see FIG. 1). The insulating layer 25 and the transparent electrode 27 are formed on the p-type semiconductor layer 21. The p-electrode 29 and the second multilayer reflector 31 are formed on the transparent electrode 27.

The insulating layer 25 has an opening 25H, which is the above-described circular opening of the insulating layer 25 that exposes the p-type semiconductor layer 21. As illustrated in FIG. 2, the opening 25H is formed at the center of the insulating layer 25 when viewed from an upper side of the surface emitting laser 10 and is covered with the second multilayer reflector 31 when viewed from the upper side of the surface emitting laser 10. In other words, the opening 25H is formed in a region of the insulating layer 25 opposed to a lower surface of the multilayer reflector 31. In this embodiment, the opening 25H has a diameter of 10 μm.

The opening 25H has a circular shape having the center on the center axis AX1. Accordingly, the p-type semiconductor layer 21 is electrically connected to the transparent electrode 27 via an electrical contact surface 21S in a circular region exposed from the opening 25H on the upper surface of the p-type semiconductor layer 21.

As shown in FIG. 2, the convex portion 11P (bold dashed line in the drawing) has a circular shape having the center on the center axis AX1 in a top view. The convex portion 11P is formed over a region on the lower surface of the substrate 11 opposed to the electrical contact surface 21S. The convex portion 11P is formed so as to overlap with the electrical contact surface 21S in a top view, that is, when viewed in a normal direction of the upper surface of the substrate 11, and extends to an outside of an outer edge, or an outline of the electrical contact surface 21S. In this embodiment, the convex portion 11P extends to an outside of the p-electrode 29 in a top view, that is, to an outside of the upper portion 17B of the n-type semiconductor layer 17.

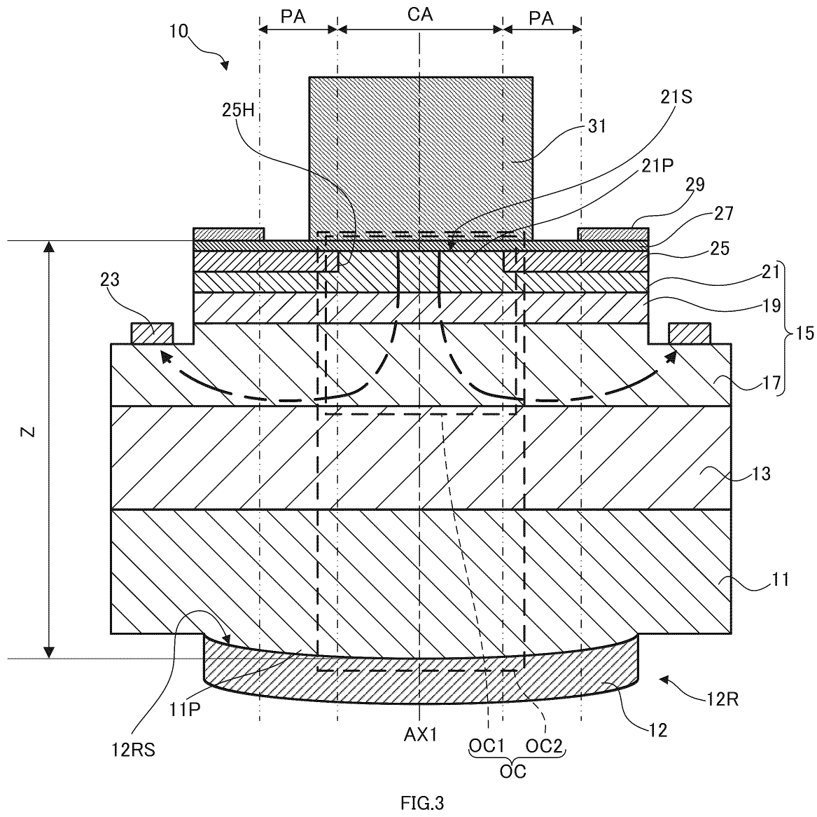

FIG. 3 is a cross-sectional view of the surface emitting laser 10 taken along the line 3-3 in FIG. 2. As described above, the surface emitting laser 10 has the substrate 11 as the GaN substrate, and the first multilayer reflector 13 is formed on the substrate 11.

As described above, the back surface multilayer reflector 12 as a third multilayer reflector is formed on the surface of the convex portion 11P on the lower surface of the substrate 11. Accordingly, the convex portion 11P and the back surface multilayer reflector 12 form the concave reflective structure 12R having an upward concave reflecting surface opposed to the active layer 19 and the second multilayer reflector 31.

With this upward concave reflecting surface, light that has passed downward through the first multilayer reflector 13 from a direction of the active layer 19 is reflected upward while being narrowed down toward the center axis AX1. That is, the back surface multilayer reflector 12 has a function of collecting the light that has passed through the first multilayer reflector 13 and reached the back surface multilayer reflector 12 in a region along the center axis AX1.

As described above with respect to FIG. 1, the semiconductor structure layer 15 is formed on the first multilayer reflector 13. The semiconductor structure layer 15 is a laminated body made by forming the n-type semiconductor layer 17, the active layer 19, and the p-type semiconductor layer 21 in this order. At the center on the upper surface of the p-type semiconductor layer 21, a projecting portion 21P projecting upward is formed.

In this embodiment, the n-type semiconductor layer 17 is an n-GaN layer having a layer thickness of 350 nm doped with Si. The active layer 19 is an active layer having a multiple quantum well structure in which four pairs of GaInN layers of 3 nm and GaN layers of 4 nm are laminated. On the active layer 19, an undoped GaN layer of 120 nm and an electronic barrier layer of AlGaN (Al composition 30%) doped with Mg of 10 nm are formed, and the p-type semiconductor layer 21 made of a p-GaN layer having a layer thickness of 83 nm at a portion where the projecting portion 21P is formed is formed thereon.

The insulating layer 25 is formed to cover a region of the upper surface of the p-type semiconductor layer 21 other than the projecting portion 21P. The insulating layer 25 is made of a material having a refractive index lower than that of the p-type semiconductor layer 21 as described above. The insulating layer 25 has the opening 25H that exposes the projecting portion 21P. For example, the opening 25H and the projecting portion 21P have similar shapes, and an inner surface of the opening 25H is in contact with an outer surface of the projecting portion 21P.

The insulating layer 25 is a layer made of SiO₂ of 20 nm. The upper surface of the insulating layer 25 is configured to be located at the same height position as am upper surface of the projecting portion 21P of the p-type semiconductor layer 21. In other words, the projecting portion 21P on the upper surface of the p-type semiconductor layer 21 projects by 20 nm from a region around the projecting portion 21P on the upper surface of the p-type semiconductor layer 21. Therefore, the p-type semiconductor layer 21 has a layer thickness of 83 nm at the projecting portion 21P and a layer thickness of 63 nm in a region other than the projecting portion 21P.

The transparent electrode 27 is formed to cover upper surfaces of the insulating layer 25 and the projecting portion 21P exposed from the opening 25H of the insulating layer 25. That is, the transparent electrode 27 is electrically in contact with the p-type semiconductor layer 21 in a region exposed by the opening 25H on the upper surface of the p-type semiconductor layer 21. In other words, the region exposed through the opening 25H on the upper surface of the p-type semiconductor layer 21 is the electrical contact surface 21S, which yields an electrical contact between the p-type semiconductor layer 21 and the transparent electrode 27.

The p-electrode 29 is a metal electrode as described above and formed along the outer edge of the upper surface of the transparent electrode 27. That is, the p-electrode 29 is electrically in contact with the transparent electrode 27. Accordingly, the p-electrode 29 is electrically in contact with or connected to the p-type semiconductor layer 21 via the transparent electrode 27 on the electrical contact surface 21S exposed by the opening 25H on the upper surface of the p-type semiconductor layer 21.

The second multilayer reflector 31 is formed on the upper surface of the transparent electrode 27 and in a region on the opening 25H of the insulating layer 25, in other words, a region on the electrical contact surface 21S, that is, at a central portion of the upper surface of the transparent electrode 27. A lower surface of the second multilayer reflector 31 is opposed to an upper surface of the first multilayer reflector 13 and the upper surface of the back surface multilayer reflector 12 with the transparent electrode 27 and the semiconductor structure layer 15 interposed therebetween. A first resonator OC1 is formed between the first multilayer reflector 13 and the second multilayer reflector 31, and a second resonator OC2 is formed between the back surface multilayer reflector 12 and the second multilayer reflector 31. A resonator OC that resonates light emitted from the active layer 19 includes the first resonator OC1 and the second resonator OC2.

In the surface emitting laser 10, the reflectivity of the second multilayer reflector 31 is slightly higher than a reflectivity of a reflective structure made of the back surface multilayer reflector 12 and the first multilayer reflector 13. Accordingly, a part of light resonated between the back surface multilayer reflector 12 with the first multilayer reflector 13 and the second multilayer reflector 31 transmits through the first multilayer reflector 13, the substrate 11, and the back surface multilayer reflector 12 to be taken out to the outside.

Here, an operation of the surface emitting laser 10 will be described. In the surface emitting laser 10, when a voltage is applied between the n-electrode 23 and the p-electrode 29, a current flows in the semiconductor structure layer 15 as indicated by the bold dash-dot line arrow in the drawing, and light is emitted from the active layer 19. The light emitted from the active layer 19 is repeatedly reflected between the first multilayer reflector 13 with the back surface multilayer reflector 12 and the second multilayer reflector 31 to become a resonant state (that is, to laser oscillate).

In the surface emitting laser 10, the current is injected to the p-type semiconductor layer 21 only from a portion exposed by the opening 25H, that is, the electrical contact surface 21S. Since the p-type semiconductor layer 21 is considerably thin, the current does not spread in the in-plane direction, that is, in a direction along the plane of the semiconductor structure layer 15 in the p-type semiconductor layer 21.

Accordingly, in the surface emitting laser 10, the current is supplied only to a region immediately below the electrical contact surface 21S defined by the opening 25H in the active layer 19 and the light is emitted only from this region. That is, in the surface emitting laser 10, the opening 25H has a current confinement structure that restricts a supply range of the current in the active layer 19. That is, in the surface emitting laser, the p-type semiconductor layer 21 and the insulating layer 25 form the current confinement structure.

In other words, in the surface emitting laser 10, between the first multilayer reflector 13 and the second multilayer reflector 31, the current confinement structure is formed which confines the current such that the current flows in the active layer 19 only to a central region CA, which is a columnar region with the electrical contact surface 21S as a bottom surface, that is, concentrates the current in one region of the active layer. The central region CA including the region through which the current flows in the active layer 19 is defined by the electrical contact surface 21S.

As described above, in this embodiment, the first multilayer reflector 13 has the reflectivity lower than that of the second multilayer reflector 31. Accordingly, a part of light coming from the second multilayer reflector 31 and the active layer 19 and reaching the first multilayer reflector 13 transmits through the back surface multilayer reflector 12, and a resonance also occurs between the second multilayer reflector 31 and the back surface multilayer reflector 12. A part of the resonated light transmits through the first multilayer reflector 13, the back surface multilayer reflector 12, and the substrate 11 to be taken out to the outside.

Thus, the surface emitting laser 10 emits the light in the direction perpendicular to the lower surface excluding the convex portion 11P of the substrate 11 and the in-plane directions of the respective layers of the semiconductor structure layer 15 from the lower surface of the substrate 11. In other words, the lower surface of the substrate 11 is a light-emitting surface of the surface emitting laser 10.

Note that the electrical contact surface 21S of the p-type semiconductor layer 21 of the semiconductor structure layer 15 and the opening 25H of the insulating layer 25 define a luminescence center as the center of a light emission region in the active layer 19 and define a center axis (a luminescence center axis) of the resonator OC. The center axis of the resonator OC passes through the center of the electrical contact surface 21S of the p-type semiconductor layer 21 and extends along the direction perpendicular to the in-plane direction of the semiconductor structure layer 15. In this embodiment, the luminescence center axis of the resonator OC is described as the same as the center axis AX1. In the following description, the center axis AX1 is also referred to as the luminescence center axis AX1.

The light emission region of the active layer 19 is, for example, a region having a predetermined width through which light having a predetermined intensity or more is emitted in the active layer 19, and its center is the luminescence center. For example, the light emission region of the active layer 19 is a region to which a current having a predetermined density or more is injected in the active layer 19, and its center is the luminescence center. A straight line perpendicular to the upper surface of the substrate 11 or the in-plane directions of the respective layers of the semiconductor structure layer 15 passing through the luminescence center is the luminescence center axis AX1. The luminescence center axis AX1 is a straight line that extends along a resonator length direction of the resonator OC constituted of the first multilayer reflector 13 with the back surface multilayer reflector 12 and the second multilayer reflector 31. The luminescence center axis AX1 corresponds to an optical axis of laser light emitted from the surface emitting laser 10.

The following describes optical features of an inside of the surface emitting laser 10. As described above, in the surface emitting laser 10, the insulating layer 25 has a refractive index lower than that of the p-type semiconductor layer 21. Layer thicknesses of the active layer 19 and the n-type semiconductor layer 17 between the back surface multilayer reflector 12 with the first multilayer reflector 13 and the second multilayer reflector 31 are the same at any positions in plane insofar as in the same layer.

Accordingly, an equivalent refractive index (an optical distance between the back surface multilayer reflector 12 with the first multilayer reflector 13 and the second multilayer reflector 31, which corresponds to a resonant wavelength) in the resonator OC formed between the back surface multilayer reflector 12 with the first multilayer reflector 13 and the second multilayer reflector 31 of the surface emitting laser 10 differs in the central region CA in a column shape with the electrical contact surface 21S as a bottom surface and in a peripheral region PA in a pipe shape around the central region CA by a difference in refractive index between the p-type semiconductor layer 21 and the insulating layer 25.

Specifically, the equivalent refractive index in the peripheral region PA is lower than the equivalent refractive index in the central region CA, that is, an equivalent resonant wavelength in the central region CA is smaller than an equivalent resonant wavelength in the peripheral region PA between the back surface multilayer reflector 12 with the first multilayer reflector 13 and the second multilayer reflector 31. Note that, somewhere the light is emitted in the active layer 19 is the region immediately below the opening 25H and the electrical contact surface 21S. That is, the light emission region where the light is emitted in the active layer 19 is a portion overlapping with the central region CA in the active layer 19, in other words, a region overlapping with the electrical contact surface 21S in a top view.

Thus, in the surface emitting laser 10, the p-type semiconductor layer 21 and the insulating layer 25 that form the current confinement structure form the central region CA including the light emission region of the active layer 19 and the peripheral region PA that surrounds the central region CA and has the refractive index lower than that of the central region CA.

This reduces an optical loss caused by diffusion (radiation) of a standing wave within the central region CA into the peripheral region PA. That is, a large quantity of light remains in the central region CA and laser light is taken out to the outside in this state.

That is, in the surface emitting laser 10, the p-type semiconductor layer 21 and the insulating layer 25 that form the current confinement structure also form a light confinement structure that retains, or confines light in the central region.

In the surface emitting laser 10, the light that has passed through the first multilayer reflector 13 and reached the back surface multilayer reflector 12 is collected in the central region CA by the concave reflecting surface 12RS of the concave reflective structure 12R formed of the back surface multilayer reflector 12. That is, the back surface multilayer reflector 12 also retains light in the central region CA.

Accordingly, the above-described current confinement structure and the back surface multilayer reflector 12 concentrate a large quantity of light in the central region CA in a peripheral area of the luminescence center axis AX1 of the resonator OC, allowing generation and emission of laser light with high output and high density.

In the surface emitting laser 10, as described above, the resonator OC is formed of the back surface multilayer reflector 12 with the first multilayer reflector 13 and the second multilayer reflector 31. This facilitates enlarging the light emission region and increasing a light output by enlarging the region through which the current flows of the active layer 19, what is called a current injecting region, while maintaining emitted light from the surface emitting laser 10 in a single mode.

For example, a configuration will be considered in which the back surface multilayer reflector 12 is excluded from the surface emitting laser 10 of the present application, and the reflectivity of the first multilayer reflector 13 is brought close to that of the second multilayer reflector 31 to form the resonator only with them (hereinafter also referred to as a comparative configuration). The present inventor has found that, in this case, unless a diameter of the opening 25H forming the current confinement structure that restricts the flow of current into the active layer 19 to define the light emission region is about 5.5 μm or less, the light to be taken out is less likely to be single-mode.

In other words, it has been found that in the comparative configuration in which the transverse mode is controlled to be single-mode by simply confining light with the structure forming the current confinement structure, the current injecting region must be kept small. This is because, when the light output is increased by enlarging the current injecting region of the active layer, a spatial hole burning occurs in the vicinity of the luminescence center of the active layer, reducing an optical gain in the vicinity of the luminescence center.

The spatial hole burning is a phenomenon in which an excessively increased light density in a certain region of the active layer leads to increased stimulated emission, and injected carriers are consumed in the region with the high light density, resulting in a low carrier density.

In the above-described comparative configuration, when the light output is attempted to be increased, the opening 25H larger than 5.5 μm causes the hole burning since the light confinement effect produced by the current confinement structure causes the light to concentrate too much around the luminescence center of the active layer, resulting in an excessively increased light density. When the hole burning occurs in the surface emitting laser, an optical gain of the resonator in the width direction has a plurality of peaks, and the transverse mode of the light taken out becomes multimode. In the surface emitting laser 10 of this embodiment, as described above, the back surface multilayer reflector 12 and the first multilayer reflector 13 form a reflective structure that reflects light upward, the second multilayer reflector 31 forms a reflective structure that reflects light downward, and these reflective structures form a resonator.

Thus, in the surface emitting laser 10, a part of light from the first resonator OC1 made of the first multilayer reflector 13 and the second multilayer reflector 31 is passed through the first multilayer reflector 13 and directed downward. This forms the second resonator OC2 also between the back surface multilayer reflector 12 having the concave reflecting surface 12RS that reflects light while narrowing down the light toward the center axis AX1 and the second multilayer reflector 31.

Thus, in the active layer 19, the light density in a region around the luminescence center axis AX1 can be reduced and the occurrence of the spatial hole burning can be suppressed as compared with the case where the first resonator OC1 is simply formed only between the first multilayer reflector 13 and the second multilayer reflector 31.

Specifically, the surface emitting laser 10 adopts not only the light confinement structure formed between the first multilayer reflector 13 and the second multilayer reflector 31, but also another lateral light confinement structure that collects light in the central region CA with the back surface multilayer reflector 12. Since the reflectivity of the first multilayer reflector 13 is low as described above, the light confinement effect by the above-described current confinement structure, which is strongly generated in the first resonator OC1 between the first multilayer reflector 13 and the second multilayer reflector 31, becomes more moderate than in the conventional art.

In the surface emitting laser 10, the light confinement effect by the above-described current confinement structure becomes moderate compared with the comparative configuration in which resonance occurs only in the first resonator OC1 between the first multilayer reflector 13 and the second multilayer reflector 31 described above. Instead, the back surface multilayer reflector 12 having the concave reflecting surface 12RS that causes the light passing through the first multilayer reflector 13 and directed downward to be reflected upward while narrowing it down toward the center axis AX1 compensates for the light confinement effect by the current confinement structure that becomes moderate.

Thus, while performing the light confinement with a combination of the above-described current confinement structure and the back surface multilayer reflector 12 allows sufficiently confining light in the central region CA, light is not excessively concentrated in the region of the active layer 19 in the vicinity of the center axis AX1, avoiding the excessively high light density. Accordingly, even when the current injecting region of the active layer 19 is large, the hole burning due to the excessively high light density is less likely to occur.

Thus, in the surface emitting laser 10, even when the opening 25H is enlarged to enlarge the current injecting region of the active layer 19, no hole burning occurs, and the light intensity distribution of emitted light is easily maintained in a Gaussian distribution. That is, in the surface emitting laser 10, the transverse mode of the emitted light is easily kept in a single mode.

The curvature radius R of the concave reflecting surface 12RS of the concave reflective structure 12R preferably satisfies the following formula (1).

$$[ Math . 1 ]$$

$$R > \frac{7.4 {n}_{eq}^{2} {π}^{2}}{{λ}_{la sin g}^{2} Z} + Z \qquad ( 1 )$$

Here, Z is originally a distance between the reflecting surface of the concave reflective structure and the active layer 19. However, since a distance between the active layer 19 and the lower surface of the second multilayer reflector 31 is small enough to be approximated, Z is set to be a distance between the reflecting surface of the concave reflective structure 12R and the lower surface of the second multilayer reflector 31 (see FIG. 3).

n_{eq} is an equivalent refractive index due to the semiconductor between the reflecting surface of the concave reflective structure 12R and the lower surface of the second multilayer reflector 31, and λ_{lasing} is a wavelength of the light emitted from the active layer 19.

This relationship has been derived based on @o, which is a distance from a peak position to a position where the light intensity is 1/e of the peak in the light intensity distribution in the plane perpendicular to the emission direction of the emitted light from the surface emitting laser 10 at the first resonator OC1, that is, ½ of a beam spot diameter, and the following formula (2).

$$[ Math . 2 ]$$

$${ω}_{0} = \sqrt{\frac{{λ}_{la sin g}}{{n}_{eq} π} \sqrt{RZ - {Z}^{2}}} \qquad ( 2 )$$

The above formula (1) is derived from the above formula (2) showing a relation between ω₀ and R. Specifically, it is derived by introducing a condition that the spot diameter wo of the light output by the first resonator OC1 is at most 1.65 μm and a condition that the spot diameter of the light output by the second resonator OC2 is preferably larger than this into the above formula (2).

As described above, in the surface emitting laser 10 of this embodiment, the upper surface of the substrate 11 is a surface offset by 0.5° in the direction from the C-plane to the M-plane. As with the surface emitting laser 10 of this embodiment, when a semiconductor layer is grown on a growth surface offset to the M-plane of the substrate 11, an optical gain of light having a polarization direction in the m-axis direction is larger than that of light having a polarization direction in another direction. Accordingly, laser light having a polarization direction in the m-axis direction easily oscillates. Therefore, the light emitted from the central region CA of the surface emitting laser 10 is mostly light having a polarization direction in the m-axis direction. That is, the surface emitting laser 10 mostly emits light having a polarization direction in a direction along the lateral axis AX2.

As described above, with the surface emitting laser of the present invention, it is easy to increase a light emitting output while maintaining the transverse mode of the emitted light in a single mode. In addition, it is possible to have high luminous efficiency and stably obtain emitted light in a specific polarization direction. This is very effective when the emitted light of the surface emitting laser is used in a device having an optical system using a liquid crystal or a polarizer.

### Manufacturing Method

The following describes an example of a method for manufacturing the surface emitting laser 10. First, as the substrate 11, an n-GaN substrate having an upper surface that is a crystal face inclined from the C-plane to the M-plane as described above is prepared.

Next, an n-GaN layer (layer thickness 1 μm) is formed as a base layer on the upper surface of the substrate 11 by metal-organic vapor phase epitaxy (MOVPE).

Then, 35 pairs of n-GaN/AlInN layers are deposited on the base layer to form the first multilayer reflector 13.

Next, Si-doped n-GaN (layer thickness 350 nm) is formed on the first multilayer reflector 13 to form the n-type semiconductor layer 17, and four pairs of layers made of GaInN (layer thickness 3 nm) and GaN (layer thickness 4 nm) are laminated on top of the n-type semiconductor layer 17 to form the active layer 19. Next, an electronic barrier layer (10 nm) made of Mg-doped AlGaN (Al composition 30%) is formed on the active layer 19 (not illustrated), and a p-GaN layer (layer thickness 83 nm) is deposited on the electronic barrier layer to form the p-type semiconductor layer 21.

Next, peripheral portions of the p-type semiconductor layer 21, the active layer 19, and the n-type semiconductor layer 17 are etched to form a mesa shape such that the upper surface 17S of the n-type semiconductor layer 17 is exposed in the peripheral portions. In other words, in this step, the semiconductor structure layer 15 having a portion on the column including the n-type semiconductor layer 17, the active layer 19, and the p-type semiconductor layer 21 in FIG. 1 is completed.

Next, a peripheral area of the center of the upper surface of the p-type semiconductor layer 21 is etched to form the projecting portion 21P. Then, 20 nm of SiO₂ is deposited on the semiconductor structure layer 15, and by removing a part thereof to form the opening 25H, the insulating layer 25 is formed. In other words, SiO₂ is embedded in an etched and removed portion of the upper surface of the p-type semiconductor layer 21.

Next, 20 nm of ITO is deposited on the insulating layer 25 to form the transparent electrode 27, and Au is deposited on the upper surface of the transparent electrode 27 and the upper surface 17S of the n-type semiconductor layer 17 to form the p-electrode 29 and the n-electrode 23, respectively.

Next, 38 nm of Nb₂O₅ is deposited on the transparent electrode 27 as a spacer layer (not illustrated), and 10.5 pairs of layers, a pair of which is made of Nb₂O₅/SiO₂, are deposited on the spacer layer to form the second multilayer reflector 31.

Next, a back surface of the substrate 11 is polished so as to have a thickness of 200 μm or less, and then the convex portion 11P is formed on the back surface of the substrate 11. The convex portion 11P is formed by a reflow process such that a center axis of the lens shape thereof coincides with the luminescence center axis AX1. The convex portion 11P may be formed by exposure patterning and dry etching.

Specifically, for example, the convex portion 11P may be formed by depositing a resist on the back surface of the substrate 11 in a shape similar to the convex portion 11P, dry etching the entire back surface of the substrate 11, thereby transferring the shape of the resist to the back surface of the substrate 11.

### Modification 1

The following describes a surface emitting laser 40 as Modification 1 of the surface emitting laser 10 of Embodiment 1 of the present invention. Modification 1 is different from the surface emitting laser 10 in that the convex portion 11P is not circular, that is, the concave reflecting surface formed by the concave reflective structure 12R is not circular.

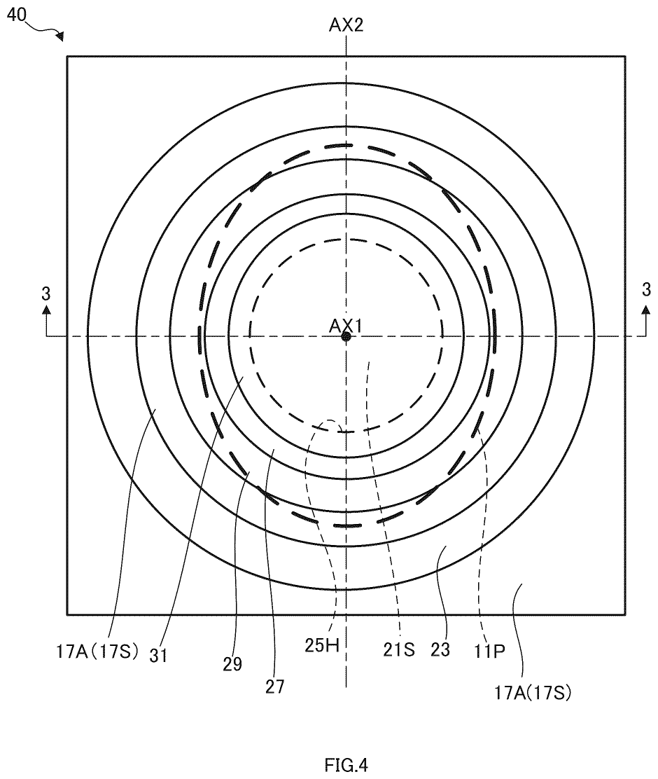

FIG. 4 is a top view of the surface emitting laser 40 of Modification 1. As shown in FIG. 4, in the surface emitting laser 40, an upper surface shape of the convex portion 11P has an elliptical shape with an axis in the same direction as the lateral axis AX2 as a long axis. That is, the convex portion 11P has an elliptical upper surface shape having a long axis along the m-axis direction in a top view.

The inventor of the present invention have found that, in the surface emitting laser 40, when the convex portion 11P has an elliptical shape having a long axis in the m-axis direction, that is, when the reflecting surface of the concave reflective structure 12R is a reflecting surface having an elliptical upper surface shape having a long axis in the m-axis direction, an optical gain of the light having a polarization direction along the m-axis direction in the central region CA increases, and a loss in the m-axis direction is decreases.

Accordingly, with the surface emitting laser 40, a large quantity of light having the polarization direction along the m-axis direction can be taken out from the lower surface of the substrate 11, which is the light-emitting surface of the surface emitting laser 10, and emission of light having a polarization direction other than the direction along the m-axis can be suppressed. Therefore, with the surface emitting laser 40, a variation in the polarization direction of the light taken out from the light-emitting surface in the in-plane direction of the light-emitting surface can be further suppressed.

The shape of the convex portion 11P for further suppressing the variation in the polarization direction, in other words, the upper surface shape of the reflecting surface of the concave reflective structure 12R may be in another shape as long as the shape has a longitudinal direction in the direction along the lateral axis AX2. In other words, the upper surface shape of the convex portion 11P may have another shape other than an ellipse as long as the shape has a longitudinal direction in the direction along the lateral axis AX2.

For example, the upper surface shape of the convex portion 11P may be a rectangular shape or a quadrilateral shape with a longitudinal direction in the direction along the lateral axis AX2. Further, for example, the upper surface shape of the convex portion 11P may be an oval shape having an outline identical to a running track with a longitudinal direction in the direction along the lateral axis AX2 direction. Further, for example, the upper surface shape of the convex portion 11P may be a rhombic shape with a longitudinal direction in the direction along the axis AX2 direction.

### Modification 2

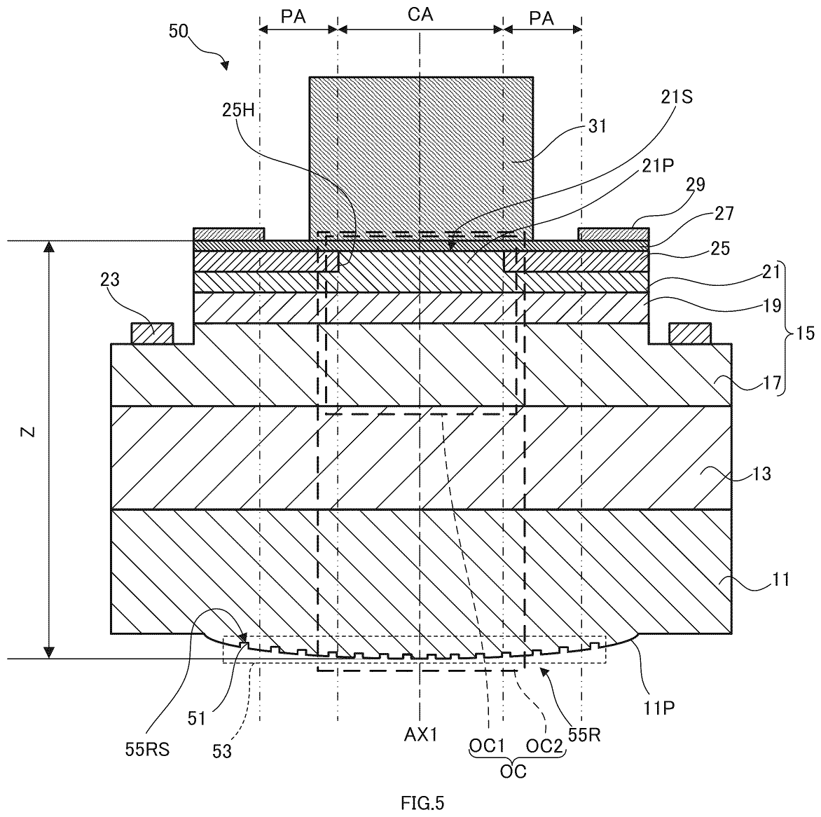

The following describes a surface emitting laser 50 as Modification 2 of the surface emitting laser 10 of Embodiment 1 of the present invention with reference to FIG. 5. The surface emitting laser 50 of Modification 2 is different from the surface emitting laser 10 of Embodiment 1 in that the back surface multilayer reflector 12 is not formed.

FIG. 5 is a cross-sectional view showing a section of the surface emitting laser 50 taken along a section line similar to that shown in FIG. 2, that is, a section corresponding to FIG. 3. As shown in FIG. 5, in the surface emitting laser 50, instead of the back surface multilayer reflector 12, a diffraction grating 53 (in the bold dashed line in the drawing) made of a plurality of slit grooves 51 is formed on the surface of the convex portion 11P. That is, the convex portion 11P and the diffraction grating 53 form a concave reflective structure 55R having a concave reflecting surface 55RS. The slit groove 51 has a longitudinal direction in the same direction as the lateral axis AX2 (see FIG. 2), which is an axis along a direction perpendicular to the paper surface of FIG. 5. That is, the slit groove 51 has a longitudinal direction in a direction along the m-axis direction in a top view.

The diffraction grating 53 formed by the slit grooves 51 yields high reflectivity to light having a polarization direction in an extending direction of the respective slit grooves 51 forming the diffraction grating, that is, the m-axis direction. That is, the diffraction grating 53 including the slit grooves 51 is formed, thereby increasing the reflectivity of the light having a polarization direction in the m-axis direction compared with light having other polarization directions and making it easier for the light having a polarization direction in the m-axis direction to oscillate preferentially.

Therefore, with the surface emitting laser 50, by forming the diffraction grating 53 including the slit grooves 51 on the lower surface of the substrate 11 to form the concave reflective structure 55R, it is possible to perform further polarization control of the emitted light and stably obtain the emitted light in which the light having one polarization direction is dominant.

Note that the slit grooves 51 can be formed by performing an etching process, such as dry etching, on the lower surface of the substrate 11 in the last step of the manufacturing process of the surface emitting laser 10 of Embodiment 1 described above.

### Modification 3

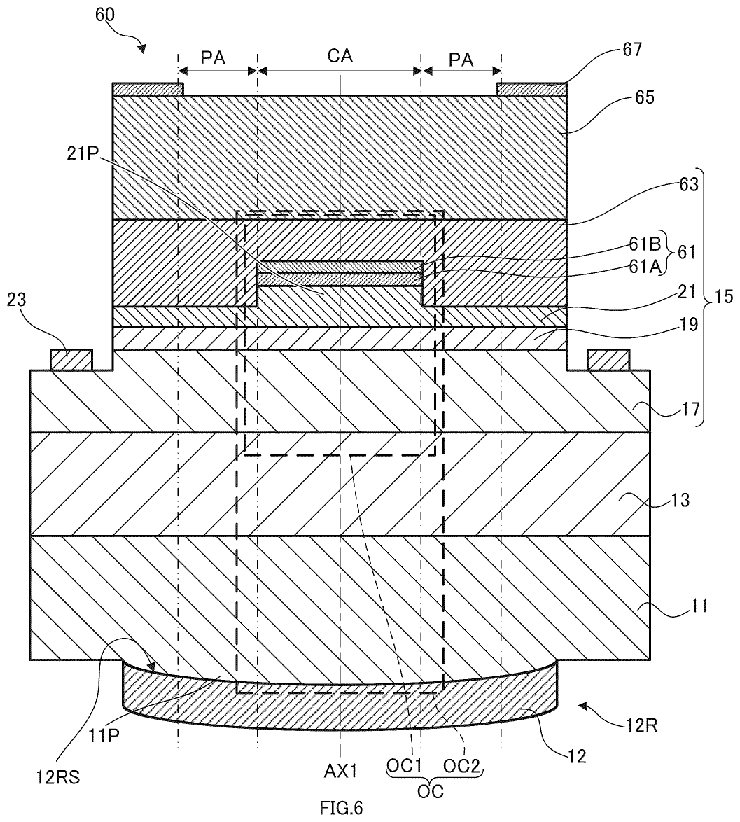

The following describes a surface emitting laser 60 as Modification 3 of Embodiment 1 of the present invention with reference to FIG. 6. The surface emitting laser 60 is different from the surface emitting laser 10 of Embodiment 1 in that, instead of the insulating layer 25, a tunnel junction structure is formed in the semiconductor structure layer 15 to form the current confinement structure described above. Specifically, the surface emitting laser 60 differs from the surface emitting laser 10 in the structure above the p-type semiconductor layer 21.

FIG. 6 is a cross-sectional view showing a section of the surface emitting laser 60 taken along a section line similar to that shown in FIG. 2, that is, a section corresponding to FIG. 3. As shown in FIG. 6, in the surface emitting laser 60, a tunnel junction layer 61 is formed on the projecting portion 21P of the p-type semiconductor layer 21. That is, in the surface emitting laser 60, the tunnel junction layer 61 is formed in the central region CA in the semiconductor structure layer 15.

The tunnel junction layer 61 includes: a high dope p-type semiconductor layer 61A that is a p-type semiconductor layer formed on the p-type semiconductor layer 21 and has an impurity concentration higher than that of the p-type semiconductor layer 21; and a high dope n-type semiconductor layer 61B that is an n-type semiconductor layer formed on the high dope p-type semiconductor layer 61A and has an impurity concentration higher than that of the n-type semiconductor layer 17.

An n-type semiconductor layer 63 is formed on the p-type semiconductor layer 21 and the tunnel junction layer 61. The n-type semiconductor layer 63 is formed to embed the tunnel junction layer 61 at the upper surface of the p-type semiconductor layer 21. In other words, the n-type semiconductor layer 63 is formed to cover a side surface of the projecting portion 21P as well as a side surface and an upper surface of the tunnel junction layer 61.

A second multilayer reflector 65 is an n-type semiconductor layer formed on an upper surface of the n-type semiconductor layer 63 and having a doping concentration similar to that of the n-type semiconductor layer 17. That is, the n-type semiconductor layer 63 has a doping concentration lower than that of the high dope n-type semiconductor layer 61B.

Such a laminated structure made of the p-type semiconductor layer 21, the tunnel junction layer 61, and the n-type semiconductor layer 63 produces a tunneling effect at the tunnel junction layer 61 portion. As a result, in the surface emitting laser 60, a current confinement structure in which a current flows only in the portion of the tunnel junction layer 61 and is confined to the central region CA is formed between the p-type semiconductor layer 21 and the n-type semiconductor layer 63.

The second multilayer reflector 65 is a semiconductor multilayer reflector made of a semiconductor layer formed on the n-type semiconductor layer 63. The second multilayer reflector 65 is formed by alternately laminating a low refractive-index semiconductor film having a composition of AlInN and a high refractive-index semiconductor film having a GaN composition and having a refractive index higher than that of the low refractive-index semiconductor film, and has n-type semiconductor properties. In other words, the second multilayer reflector 65 is a distributed Bragg reflector (DBR) made of a semiconductor material.

A p-side electrode 67 is a metal electrode formed along a peripheral edge portion of an upper surface of the second multilayer reflector 65. In the surface emitting laser 60, since the second multilayer reflector 65 has a conductive property, a current flows from the p-side electrode 67 through the second multilayer reflector 65, the n-type semiconductor layer 63, the tunnel junction layer 61, the p-type semiconductor layer 21, the active layer 19, and the n-type semiconductor layer 17 to the n-electrode 23.

In a semiconductor structure layer having this configuration, from the p-GaN layer to the n-type semiconductor layer 17, a current flows in only from the tunnel junction layer portion. Therefore, it is possible to produce the current confinement effect similar to that of the case where the insulating layer 25 is formed as described above. Since a refractive index of the tunnel junction layer 61 is different from that of the surrounding region, a light confinement effect similar to that of Embodiment 1 can also be produced.

In other words, by forming the tunnel junction layer 61 that forms a tunnel junction in the same region as the electrical contact surface 21S described above in a top view, it is possible to obtain the current confinement effect and the light confinement effect similar to those of the case where the electrical contact surface 21S is formed as described above.

While the n-electrode 23 is formed on the n-type semiconductor layer 17 in Embodiment 1 and Modifications 1 to 3 described above, an n-side electrode may be formed on the back surface of the substrate 11 instead.

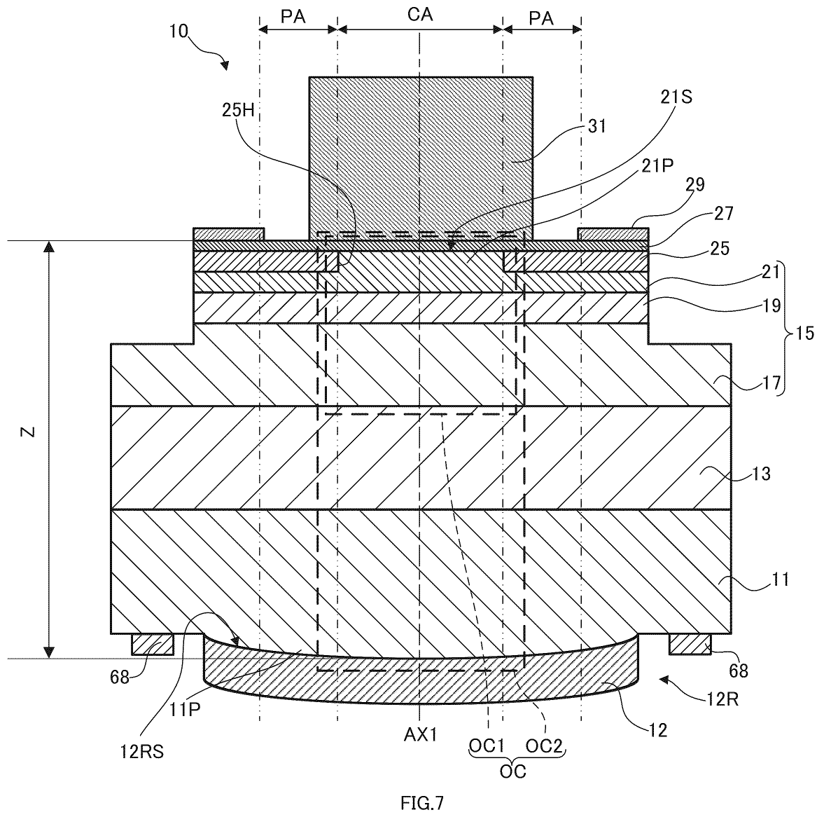

FIG. 7 shows a cross-sectional view of the surface emitting laser 10 of Embodiment 1 in which an n-side electrode 68 is formed in a region around the convex portion 11P, that is, in a region outside the concave reflective structure 12R, instead of the n-electrode 23. In this case, since the substrate 11 serves as a current path, the substrate 11 must be doped.

However, in the surface emitting laser 10, as described above, the substrate 11 preferably has high optical transparency since the substrate 11 is also disposed in the resonator. Therefore, the n-type dopant to be doped into the substrate 11 is preferably Si rather than oxygen, and a dopant concentration is preferably low. For example, in the substrate 11, in a region in the first resonator OC1 and the second resonator OC2, a region having a Si dopant concentration of 2×10¹⁸/cm³ or less preferably accounts for 80%, and more preferably, a region having a Si dopant concentration of 1×10¹⁸/cm³ or less preferably accounts for 80%.

Specifically, since the dopant concentration needs to be high in a portion forming the n-side electrode, for example, the dopant concentration is increased only in that portion, and the dopant concentration is decreased in the other regions including the resonator OC, thereby forming the substrate 11 that satisfies the above-described dopant concentration conditions. Since the portion forming the n-side electrode is a region outside the resonator OC, the dopant may be oxygen.

The above-described Modifications 1 to 3 and the example in which the n-side electrode is formed on the back surface of the substrate 11 can all be combined.

### Embodiment 2

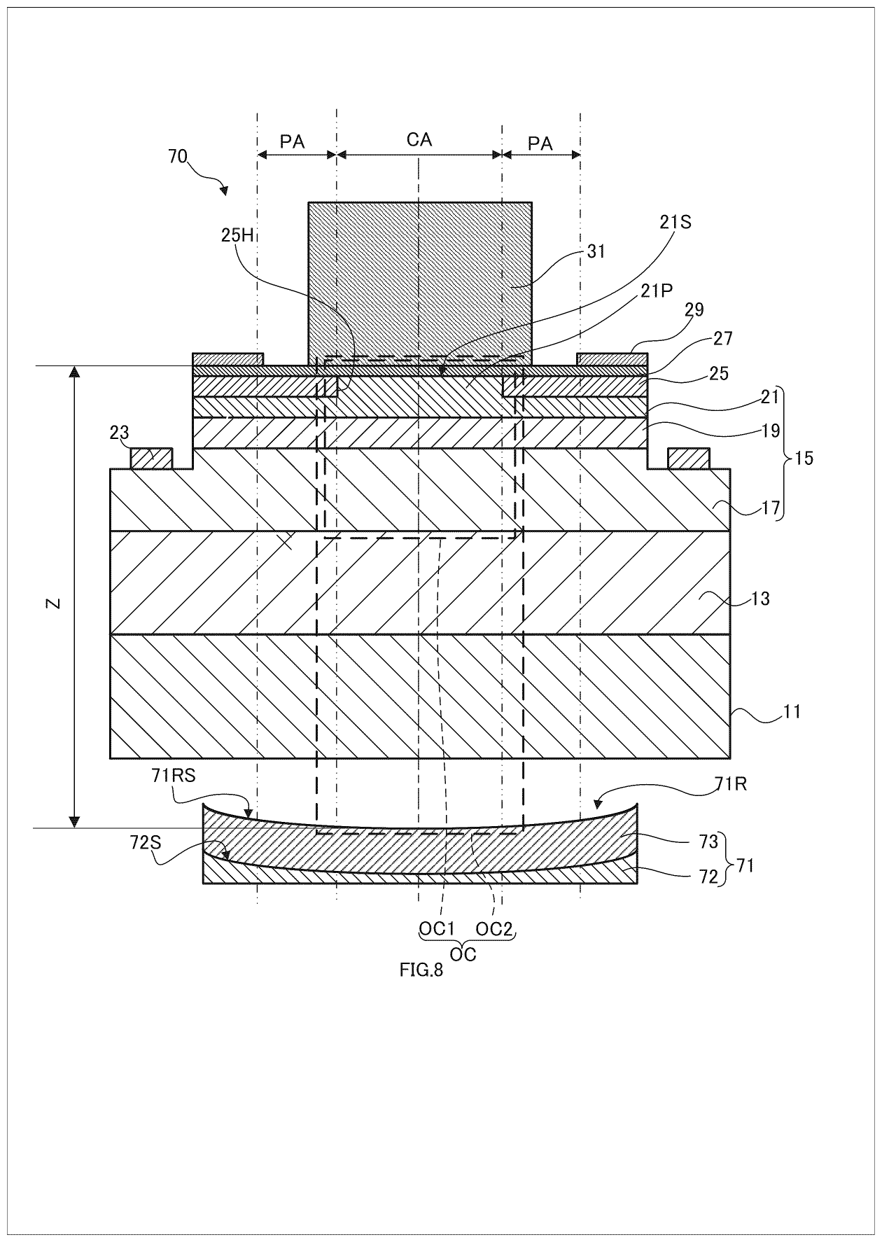

The following describes a surface emitting laser 70 as Embodiment 2 of the present invention. FIG. 8 is a cross-sectional view showing a section of the surface emitting laser 79 taken along a section line similar to that shown in FIG. 2, that is, a section corresponding to FIG. 3.

As illustrated in FIG. 8, in the surface emitting laser 70, instead of providing the convex portion 11P on the back surface of the substrate 11 to form the concave reflective structure 12R, an output coupler 71 that forms a concave reflective structure 71R having a concave reflecting surface 71RS is disposed below the substrate 11. In other words, the output coupler 71 is disposed to be spaced downward from the substrate 11.

The output coupler 71 includes a transparent substrate 72 having a concave surface 72S opposed to the lower surface of the substrate 11 and an external multilayer reflector 73 as a DBR made of a dielectric covering the concave surface 72S.

In the surface emitting laser 70, the concave reflective structure 71R corresponding to the concave reflective structure 12R of the surface emitting laser 10 is formed of the transparent substrate 72 and the external multilayer reflector 73. In the surface emitting laser 70, the second resonator OC2 is formed between the second multilayer reflector 31 and the external multilayer reflector 73.

In the surface emitting laser 10, an AR coating made of, for example, four pairs of Nb₂O₅/SiO₂ is formed on the back surface of the substrate 11 to avoid light reflection on the back surface of the substrate 11.

Such a configuration using the output coupler 71 instead of the concave reflective structure 12R with the convex portion 11P formed on the lower surface of the substrate 11 is an advantageous configuration when the concave reflective structure 12R needs to be large for the sake of design in the surface emitting laser 10.

For example, when a large number of surface emitting lasers 10 are formed on a wafer and singulated and when the concave reflective structure 12R needs to be large, the number of surface emitting lasers 10 manufactured per wafer may be limited by the size of the convex portion 11P. In such a case, replacing the concave reflective structure 12R with the concave reflective structure 71R of the external output coupler 71 allows the concave reflective structure to be large without reducing the number of surface emitting lasers manufactured per wafer.

In the above embodiments, while the case where the upper surface of the substrate 11 is a surface offset by 0.5° in the direction from the C-plane to the M-plane, that is, the case where the offset angle in the direction from the C-plane to the M-plane is 0.5° has been described, the offset angle is not limited to this angle. When the offset angle is, for example, from about 0.3° to 0.8°, the polarization control effect described above can be sufficiently obtained. When the offset angle of the upper surface of the substrate 11 is 0.8° or less, semiconductor multilayer films constituting the first multilayer reflector 13 can be formed to stably have sufficient reflectivity.

In the above embodiments, while the case where the upper surface of the substrate 11 is offset in the direction of C-plane to M-plane has been described, the upper surface of the substrate 11 may be offset in the direction from the C-plane to the A-plane and hardly offset in the C-plane direction.

In this case, in order to obtain the above polarization control effect, for reasons similar to those described for the above range of the offset angle of the C-plane, the offset angle in the direction from the C-plane to the A-plane is preferably from about 0.3° to 0.8°, and the offset angle from the C-plane to the M-plane is preferably 0±0.1°. Note that, when the upper surface of the substrate 11 is offset from the C-plane to the A-plane, it should be read differently and understood that the lateral axis AX2 corresponds to an a-axis in the description regarding the longitudinal direction of the upper surface shape of the convex portion 11P in Modification 1 and the longitudinal direction of the slit groove 51 in Modification 2 described above.

When the upper surface of the substrate 11 is offset in the direction from the C-plane to the A-plane, a large quantity of light having a polarization direction along an a-axis direction can be taken out, and emission of light having a polarization direction other than the direction along the a-axis can be suppressed. Therefore, with the surface emitting laser 10, a variation in the polarization direction of the light taken out from the light-emitting surface in the in-plane direction of the light-emitting surface can be suppressed.

When the effect of suppressing the variation in the polarization direction due to the presence of the offset angle described above is not required, the substrate 11 may be a C-plane substrate with the C-plane exposed on the upper surface.

Various values, dimensions, materials, and the like in Embodiments described above are merely examples, and can be appropriately selected depending on the usage and the surface emitting laser to be manufactured.

### DESCRIPTION OF REFERENCE SIGNS

10, 40, 50, 60, 70 Surface emitting laser
11 Substrate
12 Back surface multilayer reflector
12R Concave reflective structure
13 First multilayer reflector
15 Semiconductor structure layer
17 n-type semiconductor layer
19 Active layer
21 p-type semiconductor layer
23 n-electrode
25 Insulating layer
27 Transparent electrode
29 p-electrode
51 Slit groove
53 Diffraction grating
55R Concave reflective structure
31 Second multilayer reflector
61 Tunnel junction layer
63 n-type semiconductor layer
65 Second multilayer reflector
67 Second n-electrode
71 Output coupler
71R Concave reflective structure
72 Transparent substrate
73 External multilayer reflector

1. A vertical cavity light-emitting element comprising:
a gallium-nitride-based semiconductor substrate;
a first multilayer reflector made of a nitride semiconductor formed on the substrate;
a semiconductor structure layer including a first semiconductor layer, an active layer, and a second semiconductor layer, the first semiconductor layer being made of a nitride semiconductor having a first conductivity type formed on the first multilayer reflector, the active layer being made of a nitride semiconductor formed on the first semiconductor layer, the second semiconductor layer being formed on the active layer and made of a nitride semiconductor having a second conductivity type opposite to the first conductivity type;
a second multilayer reflector formed on the semiconductor structure layer, the second multilayer reflector configuring a resonator between the first multilayer reflector and the second multilayer reflector; and
a current confinement structure formed between the first multilayer reflector and the second multilayer reflector to concentrate a current in one region of the active layer,
wherein the vertical cavity light-emitting element has a concave reflective structure disposed on a lower surface of the gallium-nitride-based semiconductor substrate or in a region below the lower surface, the concave reflective structure having a concave reflecting surface that extends to an outside of the one region in a top view viewed in a direction perpendicular to an upper surface of the gallium-nitride-based semiconductor substrate and is opposed to the first multilayer reflector, and
wherein the concave reflective structure is configured so that a light reflected by the concave reflective surface is concentrated in the current confinement structure.

2. The vertical cavity light-emitting element according to claim 1, wherein the concave reflective structure includes:
a convex portion that is formed on the lower surface of the gallium-nitride-based semiconductor substrate and extends to the outside of the one region in the top view; and
a third multilayer reflector that forms the concave reflecting surface by covering a surface of the convex portion.

3. The vertical cavity light-emitting element according to claim 1, wherein the concave reflective structure includes:
a convex portion that is formed on the lower surface of the gallium-nitride-based semiconductor substrate and extends to the outside of the one region in the top view; and
a diffraction grating that includes a plurality of slit grooves formed parallel to one another on a surface of the convex portion and forms the concave reflecting surface.

4. The vertical cavity light-emitting element according to claim 1, wherein the concave reflective structure is a member that is disposed to be spaced downward from the gallium-nitride-based semiconductor substrate and has the concave reflecting surface.

5. The vertical cavity light-emitting element according to claim 1, further comprising:
a first electrode formed in a region outside the concave reflective structure in the top view on the lower surface of the gallium-nitride-based semiconductor substrate; and
a second electrode formed on an upper surface of the semiconductor structure layer,
wherein the gallium-nitride-based semiconductor substrate is doped with an n-type dopant.

6. The vertical cavity light-emitting element according to claim 5, wherein the n-type dopant is Si.

7. The vertical cavity light-emitting element according to claim 5, wherein a dopant concentration is higher in a region in contact with the first electrode of the gallium-nitride-based semiconductor substrate than in another region.

8. The vertical cavity light-emitting element according to claim 2, wherein the upper surface of the gallium-nitride-based semiconductor substrate is a surface offset from a C-plane to any one of crystal planes of an M-plane or an A-plane, and
wherein the concave reflecting surface has:
a longitudinal direction in an m-axis direction when the upper surface is offset to the M-plane, and
a longitudinal direction in an a-axis direction when the upper surface is offset to the A-plane.

9. The vertical cavity light-emitting element according to claim 3, wherein the upper surface of the gallium-nitride-based semiconductor substrate is a surface offset from a C-plane to any one of crystal planes of an M-plane or an A-plane, and
wherein each of the plurality of slit grooves extends:
in an m-axis direction when the upper surface is offset to the M-plane, and
in an a-axis direction when the upper surface is offset to the A-plane.

10. The vertical cavity light-emitting element according to claim 8, wherein the upper surface of the gallium-nitride-based semiconductor substrate is:
a surface offset by an angle of 0.8° or less from the C-plane to the M-plane when the upper surface is offset to the M-plane, and
a surface offset by an angle of 0.8° or less from the C-plane to the A-plane when the upper surface is offset to the A-plane.

11. The vertical cavity light-emitting element according to claim 1, wherein when a distance between the concave reflecting surface and the active layer is Z, an equivalent refractive index between the concave reflecting surface and the second multilayer reflector is n_{eq}, and a wavelength of emitted light from the active layer is λ_{lasing}, a curvature radius R of the concave reflecting surface of the concave reflective structure satisfies the following formula:
$$R > \frac{7.4 {n}_{eq}^{2} {π}^{2}}{{λ}_{la sin g}^{2} Z} + Z . \qquad ( 1 )$$

12. The vertical cavity light-emitting element according to claim 1, wherein the concave reflective structure is configured so that a light reflected by the concave reflective surface is not concentrated in the active layer.

13. The vertical cavity light-emitting element according to claim 12, wherein an axis passing through a center of the upper surface of the of the gallium-nitride-based substrate and perpendicular to the upper surface passes through a center of an upper surface of the current confinement structure, and
wherein the concave reflective structure is configured so that a light is reflected upward by the concave reflective surface while being narrowed down toward the axis.
